(19) United States
(12) Patent Application Publication
(10) Pub. No.: US 2023/0301116 A1
(43) Pub. Date: Sep. 21, 2023

(54) MAGNETIC MEMORY DEVICE

(71) Applicants: Kioxia Corporation, Tokyo (JP); SK hynix Inc., Icheon-si (KR)

(72) Inventors: Kenichi YOSHINO, Seongnam-si Gyeonggi-do (KR); Kazuya SAWADA, Seoul (KR); Naoki AKIYAMA, Seoul (KR); Takuya SHIMANO, Seoul (KR); Cha Deok DONG, Icheon-si Gyeonggi-do (KR); Keorock CHOI, Icheon-si Gyeonggi-do (KR); Bokyung JUNG, Icheon-si Gyeonggi-do (KR); Gukcheon KIM, Icheon-si Gyeonggi-do (KR)

(73) Assignees: Kioxia Corporation, Tokyo (JP); SK hynix Inc., Icheon-si (KR)

(21) Appl. No.: 17/943,151

(22) Filed: Sep. 12, 2022

(30) Foreign Application Priority Data
Mar. 16, 2022 (JP) 2022-041502

(51) Int. Cl. H01L 27/22; H01L 43/12

(52) U.S. Cl. CPC H01L 27/224; H01L 43/12

(57) ABSTRACT

According to one embodiment, a magnetic: memory device includes a stacked structure in which a magnetoresistance effect element and a switching element are stacked. The switching element is provided on a lower layer side of the magnetoresistance effect element, and when viewed in a stacking direction of the magnetoresistance effect element and the switching element, a pattern of the switching element is located inside a pattern of the magnetoresistance effect element.

### CROSS-REFERENCE TO RELATED APPLICATIONS

This application is based upon and claims the benefit of priority from Japanese Patent Application No. 2022-041502, filed Mar. 16, 2022, the entire contents of which are incorporated herein by reference.

### FIELD

Embodiments described herein relate generally to a magnetic memory device.

### BACKGROUND

A magnetic memory device in which a memory cell including a magnetoresistance effect element and a selector (switching element) is integrated on a semiconductor substrate has been suggested.

### BRIEF DESCRIPTION OF THE DRAWINGS

FIG. 1 is a perspective view schematically illustrating the structure of a magnetic memory device according to a first embodiment.

FIG. 2 is a cross-sectional view schematically illustrating the detailed structure of the magnetic memory device according to the first embodiment.

FIG. 3 is a pattern diagram schematically illustrating the relationship between the patterns of the structural elements of the magnetic memory device according to the first embodiment.

FIG. 4 is a cross-sectional view schematically illustrating the structure of the magnetoresistance effect element of the magnetic memory device according to the first embodiment.

FIG. 5 is a diagram schematically illustrating the current-voltage characteristics of the selector of the magnetic memory device according to the first embodiment.

FIG. 6A, FIG. 6B, FIG. 6C, FIG. 6D, FIG. 6E, FIG. 6F, FIG. 6G, FIG. 6H and FIG. 6I are cross-sectional views schematically illustrating a manufacturing method of the magnetic memory device according to the first embodiment.

FIG. 7 is a perspective view schematically illustrating the structure of a magnetic memory device according to a second embodiment.

FIG. 8 is a cross-sectional view schematically illustrating the detailed structure of the magnetic memory device according to the second embodiment.

FIG. 9 is a pattern diagram schematically illustrating the relationship between the patterns of the structural elements of the magnetic memory device according to the second embodiment.

FIG. 10A, FIG. 10B, FIG. 10C, FIG. 10D, FIG. 10E, FIG. 10F, FIG. 10G, FIG. 10H and FIG. 10I are cross-sectional views schematically illustrating a manufacturing method of the magnetic memory device according to the second embodiment.

### DETAILED DESCRIPTION

In general, according to one embodiment, a magnetic memory device includes a stacked structure in which a magnetoresistance effect element and a switching element are stacked, wherein the switching element is provided on a lower layer side of the magnetoresistance effect element, and when viewed in a stacking direction of the magnetoresistance effect element and the switching element, a pattern of the switching element is located inside a pattern of the magnetoresistance effect element.

Embodiments will be described hereinafter with reference to the accompanying drawings.

### First Embodiment

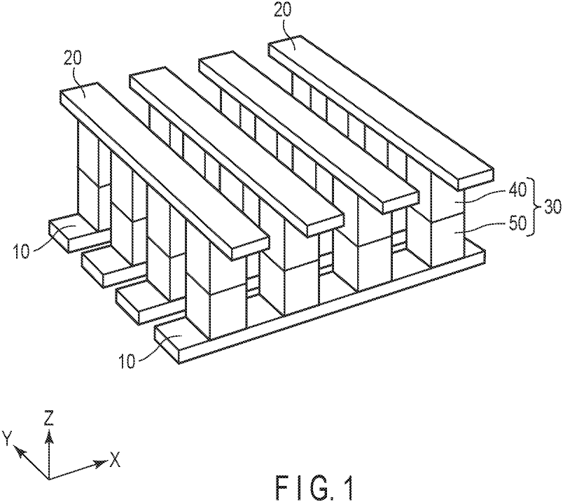

FIG. 1 is a perspective view schematically illustrating the structure of a magnetic memory device (nonvolatile magnetic memory device) according to a first embodiment.

The magnetic memory device is provided on a bottom structure (not shown) including a semiconductor substrate (not shown) and includes a first wiring line 10 extending in an X-direction, a second wiring line 20 extending in a Y-direction and a stacked structure 30 provided between the first wiring line 10 and the second wiring line 20.

One of the first wiring line 10 and the second wiring line 20 corresponds to a word line. The other of the first wiring line 10 and the second wiring line 20 corresponds to a bit line.

The stacked structure 30 comprises a structure in which a magnetoresistance effect element 40 and a selector (switching element) 50 are stacked. The selector 50 is provided on the lower layer side (semiconductor substrate side) of the magnetoresistance effect element 40. A memory cell is structured by connecting the magnetoresistance effect element 40 and the selector 50 in series.

The X-direction, the Y-direction and a Z-direction are directions intersecting one another. More specifically, the X-direction, the Y-direction and the Z-direction are orthogonal to one another.

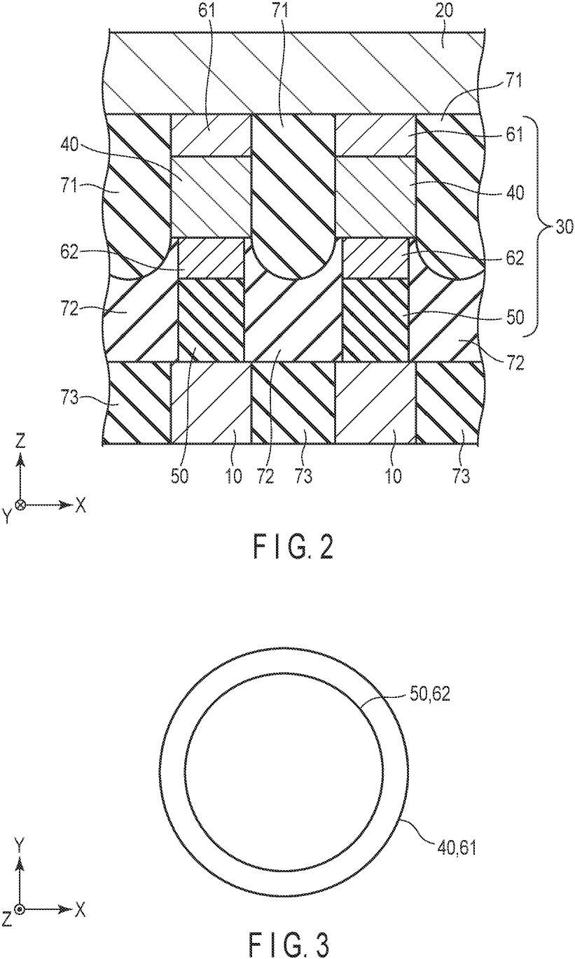

FIG. 2 is a cross-sectional view schematically illustrating the detailed structure of the magnetic memory device according to the present embodiment.

As described above, the stacked structure 30 is provided between the first wiring line 10 and the second wiring line 20. In addition to the magnetoresistance effect element 40 and the selector 50, the stacked structure 30 includes a hard mask portion 61 and a middle electrode 62. More specifically, the hard mask portion 61 is provided between the second wiring line 20 and the magnetoresistance effect element 40. The middle electrode 62 is provided between the magnetoresistance effect element 40 and the selector 50. The selector 50 is provided between the first wiring line 10 and the middle electrode 62.

In addition to a function as a hard mask, the hard mask portion 61 has a function as a top electrode for the magnetoresistance effect element 40. The middle electrode 62 has a function as a bottom electrode for the magnetoresistance effect element 40 and a top electrode for the selector 50. The first wiring line 10 also has a function as a bottom electrode for the selector 50.

FIG. 3 is a pattern diagram schematically illustrating the relationship between the patterns of the structural elements of the magnetic memory device illustrated in FIG. 2.

As illustrated in FIG. 3, when viewed in the stacking direction (Z-direction) of the magnetoresistance effect element 40 and the selector 50, the pattern (planar pattern) of the selector 50 and the middle electrode 62 is located inside the pattern (planar pattern) of the magnetoresistance effect element 40 and the hard mask portion 61. In other words, the pattern of the selector 50 and the middle electrode 62 is smaller than the pattern of the magnetoresistance effect element 40 and the hard mask portion 61.

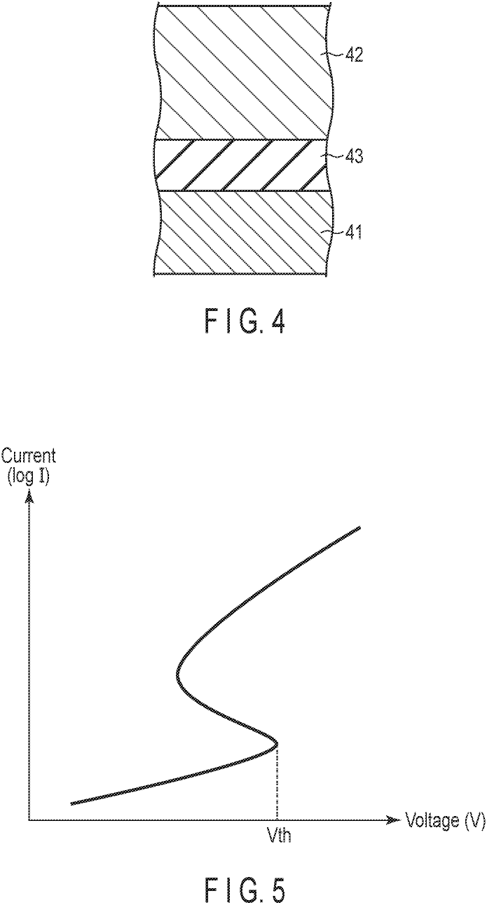

FIG. 4 is a cross-sectional view schematically illustrating the structure of the magnetoresistance effect element 40.

The magnetoresistance effect element 40 is a magnetic tunnel junction (MTJ) element and includes a storage layer (first magnetic layer) 41, a reference layer (second magnetic layer) 42 and a tunnel barrier layer (nonmagnetic layer) 43. The storage layer 41 is a ferromagnetic layer having a variable magnetization direction. The reference layer 42 is a ferromagnetic layer having a fixed magnetization direction. The tunnel barrier layer 43 is an insulating layer provided between the storage layer 41 and the reference layer 42. A variable magnetization direction means that the magnetization direction changes for a predetermined write current. A fixed magnetization direction means that the magnetization direction does not change for a predetermined write current.

When the magnetization direction of the storage layer 41 is parallel to the magnetization direction of the reference layer 42, the magnetoresistance effect element 40 is in a low resistive state where the resistance is relatively low. When the magnetization direction of the storage layer 41 is antiparallel to the magnetization direction of the reference layer 42, the magnetoresistance effect element 40 is in a high resistive state where the resistance is relatively high. Thus, the magnetoresistance effect element 40 is allowed to store binary data based on the resistive state.

As illustrated in FIG. 2, the selector 50 is provided on the lower layer side of the magnetoresistance effect element 40 and is formed of an insulating selector material (switching material). Specifically, the selector 50 is formed of silicon oxide containing arsenic (As).

FIG. 5 is a diagram schematically illustrating the current-voltage characteristics of the selector 50.

As illustrated in FIG. 5, the selector 50 has characteristics in which the state is switched from an off-state to an on-state when the voltage applied between the both ends is greater than or equal to a threshold voltage Vth. In other words, the selector 50 has characteristics in which the state is switched from an off-state to an on-state when the voltage applied between the first wiring line 10 functioning as a bottom electrode and the middle electrode 62 functioning as a top electrode is greater than or equal to a threshold voltage Vth.

When the voltage applied between the both ends of the selector 50 is made greater than or equal to a threshold voltage Vth by controlling the voltage applied between the first wiring line 10 and the second wiring line 20, the selector 50 transitions to an on-state. Thus, writing and reading can be performed for the magnetoresistance effect element 40 connected to the selector 50 in series.

As illustrated in FIG. 2, an interlayer insulating layer 71 is provided on side surfaces of the magnetoresistance effect element 40 and the hard mask portion 61. An interlayer insulating layer 72 is provided on side surfaces of the selector 50 and the middle electrode 62. Thus, the interlayer insulating layer 71 is not in contact with the side surface of the selector 50 or the middle electrode 62. Similarly, the interlayer insulating layer 72 is not in contact with the side surface of the magnetoresistance effect element 40 or the hard mask portion 61. The top surface of the interlayer insulating layer 72 is recessed. The interlayer insulating layer 71 is provided on the recessed top surface of the interlayer insulating layer 72. An interlayer insulating layer 73 is provided on a side surface of the first wiring line 10.

The interlayer insulating layer 71 is formed of a first material. The interlayer insulating layer 72 is formed of a second material which is different from the first material. For example, the first material is different from the second material in the following manner. As a first example, the first material contains an element which is not contained in the second material. Alternatively, the second material contains an element which is not contained in the first material. As a second example, all of the elements contained in the first material are the same as the elements contained in the second material, and the composition ratio of the elements contained in the first material is different from that of the elements contained in the second material.

As the first example, the following case can be considered. Oxide is used for the first material, and nitride is used for the second material. In this case, for example, silicon oxide (SiOₓ) or aluminum oxide (AlOₓ) is used for the first material, and silicon nitride (SiNₓ) is used for the second material.

As the second example, the following case can be considered. Both the first material and the second material contain silicon (Si), nitrogen (N) and hydrogen (H) (in other words, both the first material and the second material are formed of silicon nitride containing hydrogen (H)). The composition ratio of silicon (Si), nitrogen (N) and hydrogen (H) of the first material is different from that of silicon (Si), nitrogen (N) and hydrogen (H) of the second material.

In both the first example and the second example (especially, in the case of the second example), the concentration of nitrogen of the first material should be preferably lower than that of the second material, or the concentration of hydrogen of the second material should be preferably lower than that of the first material.

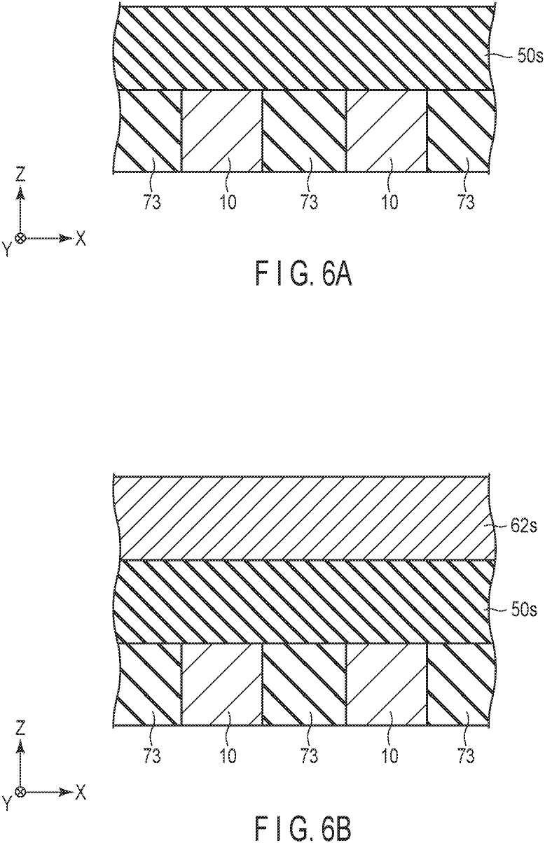

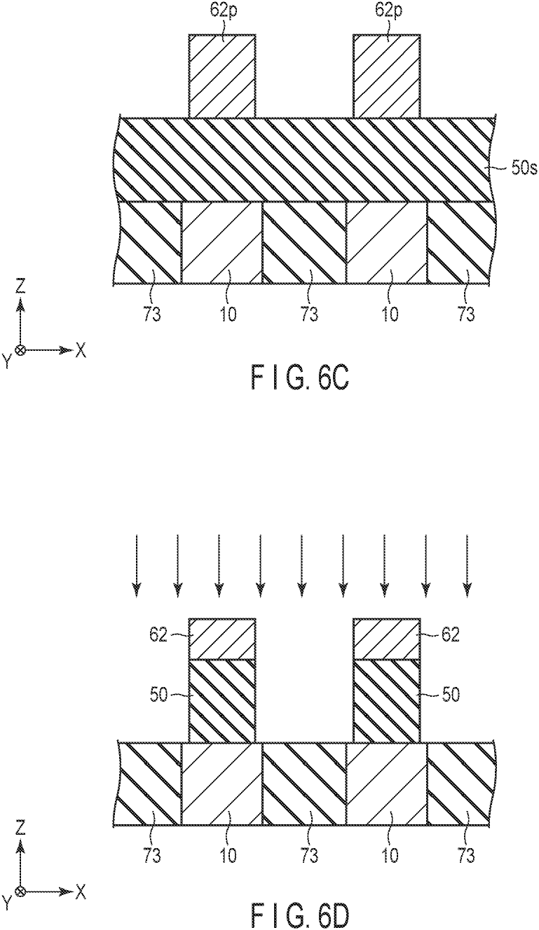

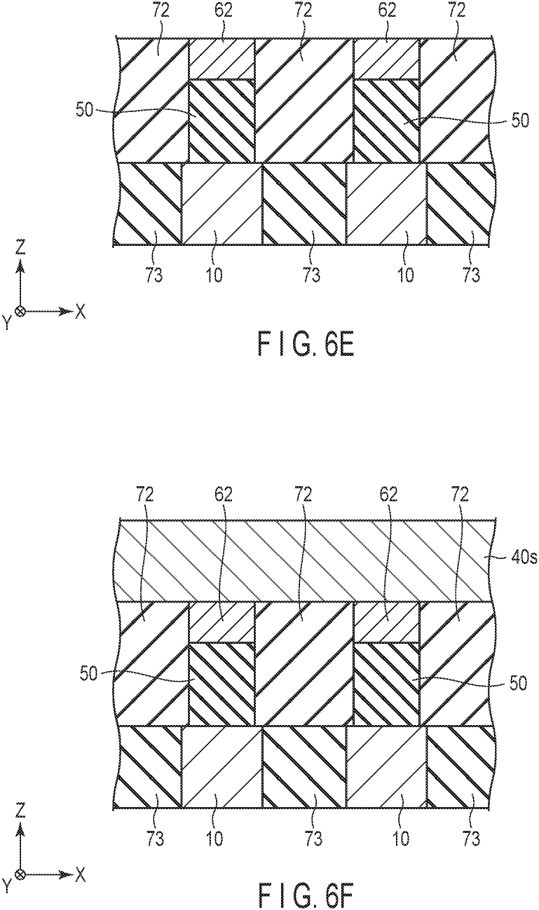

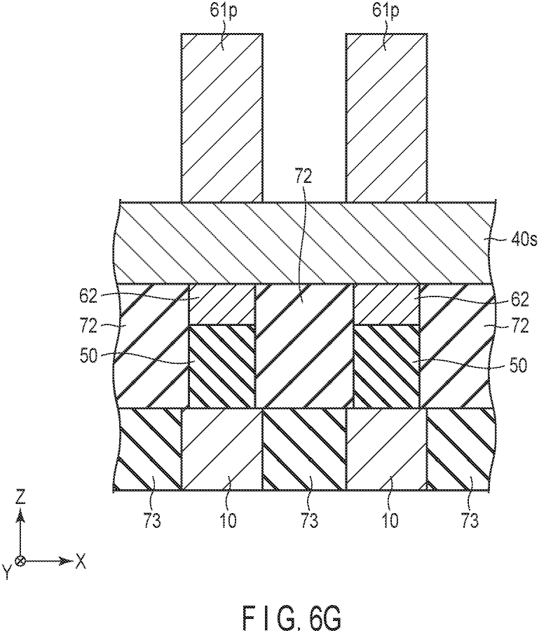

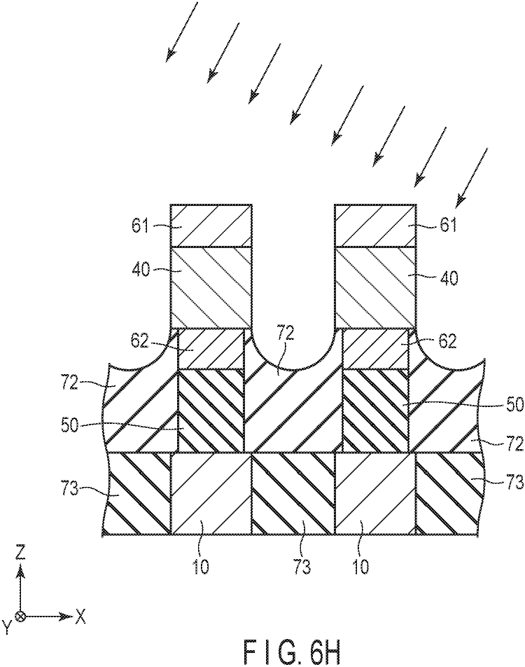

Now, this specification explains a manufacturing method of the magnetic memory device of the present embodiment with reference to FIG. 6A to FIG. 6I and FIG. 2.

First, as illustrated in FIG. 6A, the first wiring line 10 and the interlayer insulating layer 73 are formed on a bottom structure (not shown) including a semiconductor substrate (not shown), etc. Subsequently, a selector material layer 50s is formed on the first wiring line 10 and the interlayer insulating layer 73.

Subsequently, as illustrated in FIG. 6B, a middle electrode layer 62s is formed on the selector material layer 50s.

Subsequently, as illustrated in FIG. 6C, a preliminary middle electrode 62p is formed by patterning the middle electrode layer 62s.

Subsequently, as illustrated in FIG. 6D, the preliminary middle electrode 62p is used as a mask to etch the selector material layer 50s by reactive ion etching (RIE). As a result, the pattern of the selector 50 is obtained. The thickness of the preliminary middle electrode 62p is decreased, thereby obtaining the middle electrode 62.

Subsequently, as illustrated in FIG. 6E, the interlayer insulating layer 72 is formed on side surfaces of the selector 50 and the middle electrode 62 by chemical vapor deposition (CVD), etc. Specifically, after the interlayer insulating layer 72 is formed on the structure obtained by the process of FIG. 6D, the interlayer insulating layer 72 is planarized. By this process, the structure illustrated in FIG. 6E is obtained.

Subsequently, as illustrated in FIG. 6F, a magnetoresistance effect element layer 40s is formed on the structure obtained by the process of FIG. 6E.

Subsequently, as illustrated in FIG. 6G, the pattern of a preliminary hard mask portion 61p is formed on the magnetoresistance effect element layer 40s. The pattern of the preliminary hard mask portion 61p is formed such that the pattern of the selector 50 and the middle electrode 62 is located inside the pattern of the preliminary hard mask portion 61p when viewed in the Z-direction.

Subsequently, as illustrated in FIG. 6H, ion beam etching (IBE) is performed using the preliminary hard mask portion 61p as a mask. Specifically, an Ar ion beam is applied to the structure of FIG. 6G obliquely from above while rotating the substrate on which the structure of FIG. 6G is formed. By this process, the preliminary hard mask portion 61p, the magnetoresistance effect element layer 40s and the interlayer insulating layer 72 are etched. As a result, the pattern of the magnetoresistance effect element 40 is obtained. The thickness of the preliminary hard mask portion 61p is decreased, thereby obtaining the hard mask portion 61. Further, a shape in which the top surface of the interlayer insulating layer 72 is recessed is obtained.

As already described above, the pattern of the selector 50 is located inside the pattern of the preliminary hard mask portion 61p when viewed in the Z-direction. Thus, the side surface of the selector 50 can be assuredly protected by the interlayer insulating layer 72 in the above IBE process. In this way, in the IBE process described above, damage caused to the selector 50 by IBE can be prevented.

Subsequently, as illustrated in FIG. 6I, the interlayer insulating layer 71 is formed on side surfaces of the magnetoresistance effect element 40 and the hard mask portion 61 by CVD, etc. Specifically, after the interlayer insulating layer 71 is formed on the structure obtained by the process of FIG. 6H, the interlayer insulating layer 71 is planarized. By this process, the structure illustrated in FIG. 6I is obtained.

Subsequently, the second wiring line 20 is formed on the hard mask portion 61 and the interlayer insulating layer 71, thereby obtaining the structure illustrated in FIG. 2.

As described above, in the present embodiment, when viewed in the stacking direction (Z-direction) of the magnetoresistance effect element 40 and the selector 50, the pattern of the selector 50 is located inside the pattern of the magnetoresistance effect element 40. Thus, when the pattern of the magnetoresistance effect element 40 is formed by IBE, the selector 50 can be assuredly protected by the interlayer insulating layer 72, thereby preventing damage caused to the selector 50 by IBE. In this way, degradation of the characteristics of the selector 50 by the damage of IBE can be prevented. It is possible to obtain a magnetic memory device having excellent characteristics.

In the present embodiment, the interlayer insulating layer 71 formed of the first material is provided on a side surface of the magnetoresistance effect element 40. The interlayer insulating layer 72 formed of the second material is provided on a side surface of the selector 50. Thus, when the first material is selected so as to be suitable for the magnetoresistance effect element 40 (in other words, so as not to have a detrimental effect on the magnetoresistance effect element 40), and the second material is selected so as to be suitable for the selector 50 (in other words, so as not to have a detrimental effect on the selector 50), a magnetic memory device having excellent characteristics can be obtained.

### Second Embodiment

Now, this specification explains a second embodiment. As the basic matters are similar to those of the first embodiment, the matters described in the first embodiment are omitted.

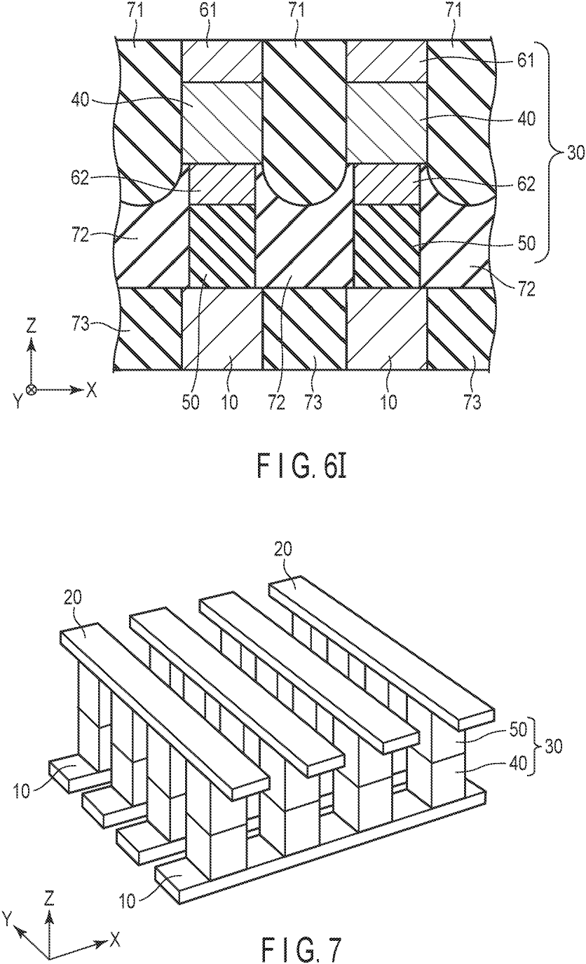

FIG. 7 is a perspective view schematically illustrating the structure of a magnetic memory device (nonvolatile magnetic memory device) according to the present embodiment.

In the first embodiment, the selector 50 is provided on the lower layer side of the magnetoresistance effect element 40. In the present embodiment, a selector 50 is provided on the upper layer side of a magnetoresistance effect element 40.

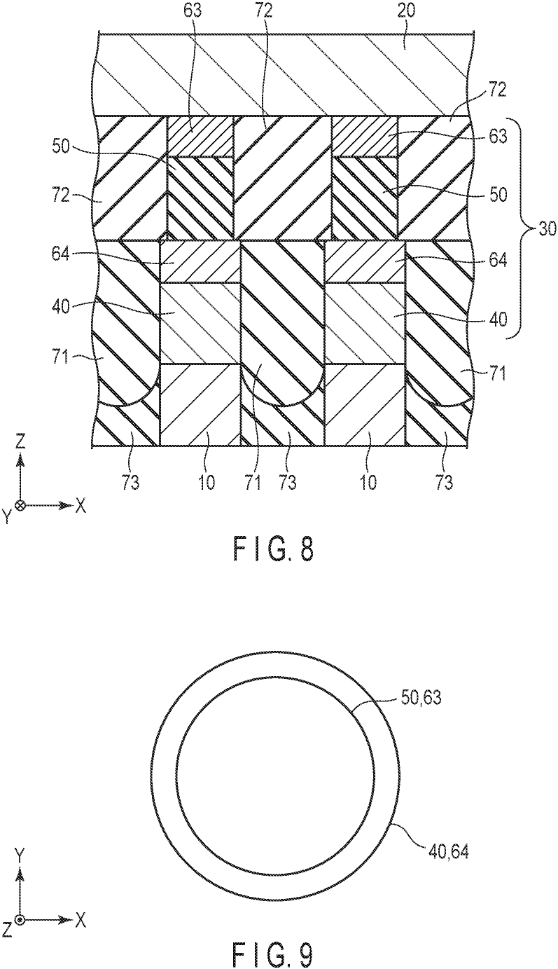

FIG. 8 is a cross-sectional view schematically illustrating the detailed structure of the magnetic memory device according to the present embodiment.

As described above, in the present embodiment, a stacked structure 30 has a structure in which the selector 50 is provided on the upper layer side of the magnetoresistance effect element 40. Specifically, a hard mask portion 63 is provided between a second wiring line 20 and the selector 50. A middle electrode 64 is provided between the magnetoresistance effect element 40 and the selector 50. The magnetoresistance effect element 40 is provided between a first wiring line 10 and the middle electrode 64.

The hard mask portion 63 has a function as a top electrode for the selector 50. The middle electrode 64 has a function as a top electrode for the magnetoresistance effect element 40 and a bottom electrode for the selector 50. The first wiring line 10 has a function as a bottom electrode for the magnetoresistance effect element 40.

FIG. 9 is a pattern diagram schematically illustrating the relationship between the patterns of the structural elements of the magnetic memory device illustrated in FIG. 8.

As illustrated in FIG. 9, when viewed in the stacking direction (Z-direction) of the magnetoresistance effect element 40 and the selector 50, the pattern (planar pattern) of the selector 50 and the hard mask portion 63 is located inside the pattern (planar pattern) of the magnetoresistance effect element 40 and the middle electrode 64. It should be noted that, in the present embodiment, the relationships of the pattern of the magnetoresistance effect element 40, the pattern of the selector 50, the pattern of the hard mask portion 63 and the pattern of the middle electrode 64 may not necessarily satisfy the relationships illustrated in FIG. 9.

As illustrated in FIG. 8, an interlayer insulating layer 71 is provided on side surfaces of the magnetoresistance effect element 40 and the middle electrode 64. An interlayer insulating layer 72 is provided on side surfaces of the selector 50 and the hard mask portion 63. Thus, the interlayer insulating layer 71 is not in contact with the side surface of the selector 50 or the hard mask portion 63. Similarly, the interlayer insulating layer 72 is not in contact with the side surface of the magnetoresistance effect element 40 or the middle electrode 64. An interlayer insulating layer 73 is provided on a side surface of the first wiring line 10.

In a manner similar to that of the first embodiment, the interlayer insulating layer 71 is formed of a first material. The interlayer insulating layer 72 is formed of a second material which is different from the first material. The same explanation as the first embodiment is applied to the first material and the second material.

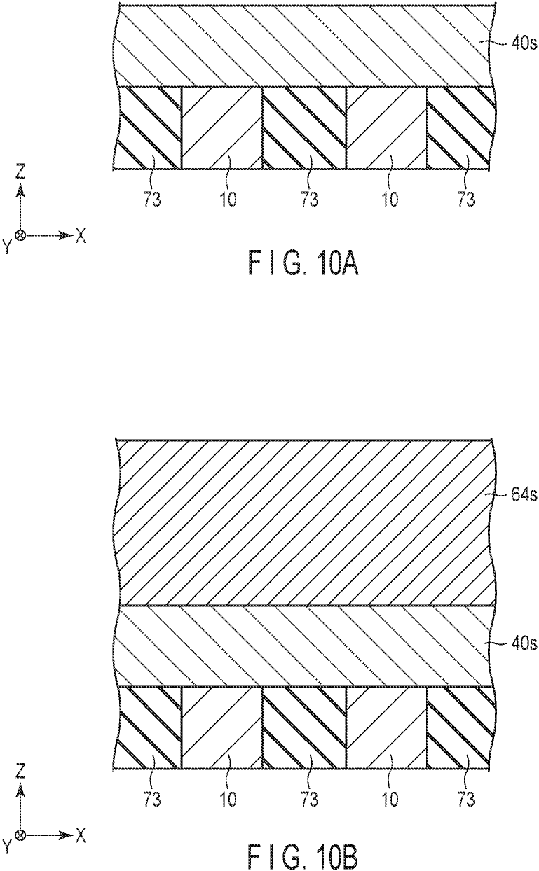

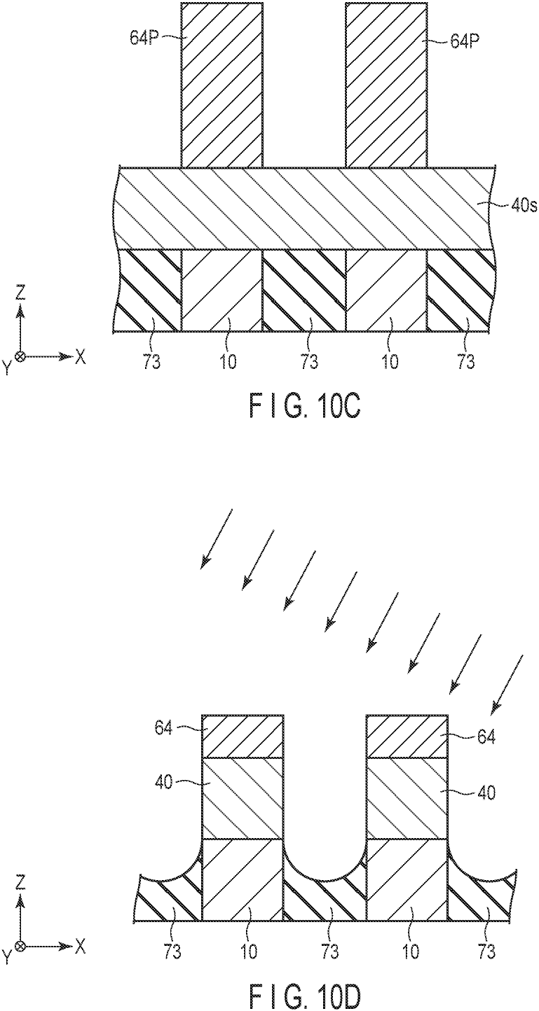

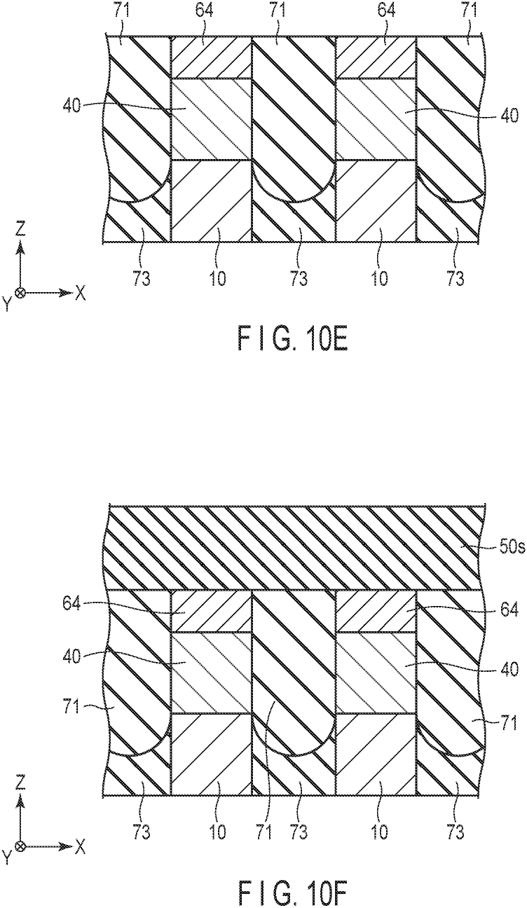

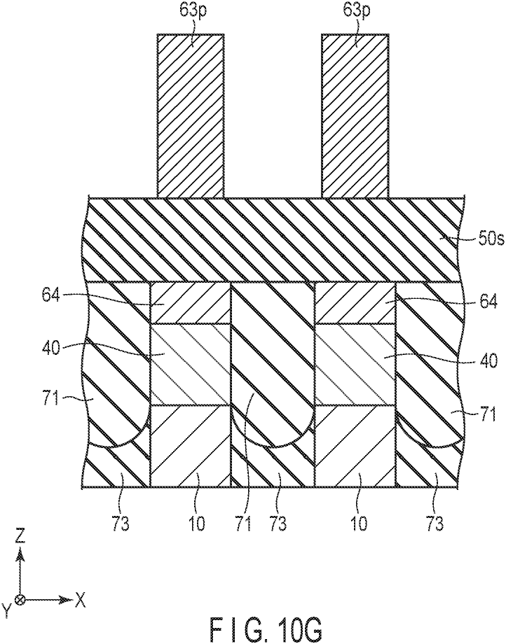

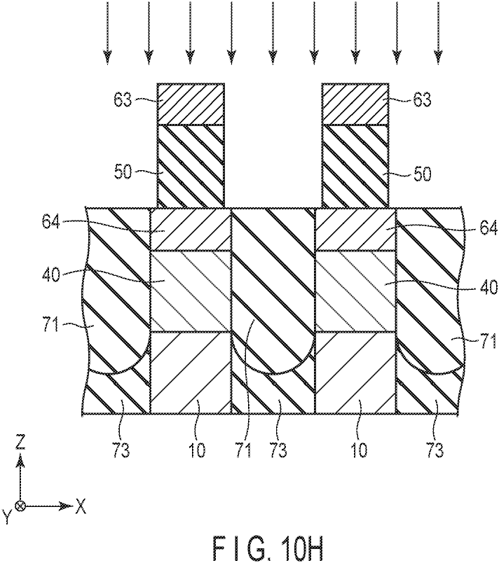

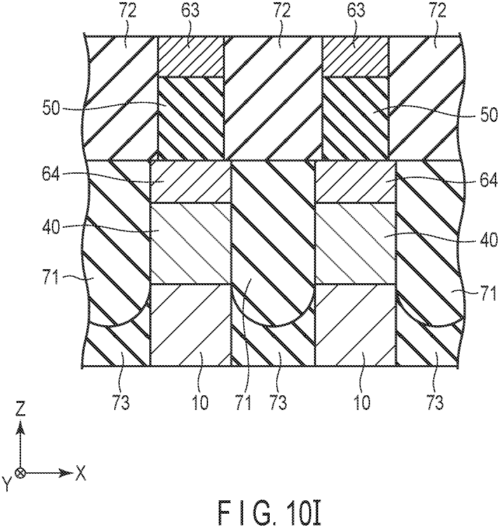

Now, this specification explains a manufacturing method of the magnetic memory device of the present embodiment with reference to FIG. 10A to FIG. 10I and FIG. 8.

First, as illustrated in FIG. 10A, the first wiring line 10 and the interlayer insulating layer 73 are formed on a bottom structure (not shown) including a semiconductor substrate (not shown). Subsequently, a magnetoresistance effect element layer 40s is formed on the first wiring line 10 and the interlayer insulating layer 73.

Subsequently, as illustrated in FIG. 10B, a middle electrode layer 64s functioning as a hard mask is formed on the magnetoresistance effect element layer 40s.

Subsequently, as illustrated in FIG. 10C, a preliminary middle electrode 64p is formed by patterning the middle electrode layer 64s.

Subsequently, as illustrated in FIG. 10D, IBE is performed using the preliminary middle electrode 64p as a mask. Specifically, an Ar ion beam is applied to the structure of FIG. 10C obliquely from above while rotating the substrate on which the structure of FIG. 10C is formed. By this process, the preliminary middle electrode 64p, the magnetoresistance effect element layer 40s and the interlayer insulating layer 73 are etched. In this way, the pattern of the magnetoresistance effect element 40 is obtained. The thickness of the preliminary middle electrode 64p is decreased, thereby obtaining the middle electrode 64. Further, a shape in which the top surface of the interlayer insulating layer 73 is recessed is obtained.

Subsequently, as illustrated in FIG. 10E, the interlayer insulating layer 71 is formed on side surfaces of the magnetoresistance effect element 40 and the middle electrode 64. Specifically, after the interlayer insulating layer 71 is formed on the structure obtained by the process of FIG. 10D by CVD, etc., the interlayer insulating layer 71 is planarized. By this process, the structure illustrated in FIG. 10E is obtained.

Subsequently, as illustrated in FIG. 10F, a selector material layer 50s is formed on the structure obtained by the process of FIG. 10E.

Subsequently, as illustrated in FIG. 10G, the pattern of a preliminary hard mask portion 63p is formed on the selector material layer 50s. The pattern of the preliminary hard mask portion 63p is formed such that the pattern of the preliminary hard mask portion 63p is located inside the pattern of the magnetoresistance effect element 40 and the middle electrode 64 when viewed in the Z-direction. It should be noted that the present embodiment may not necessarily satisfy this relationship.

Subsequently, as illustrated in FIG. 10H, the selector material layer 50s is etched by RIE, using the preliminary hard mask portion 63p as a mask. As a result, the pattern of the selector 50 is obtained. The thickness of the preliminary hard mask portion 63p is decreased, thereby obtaining the hard mask portion 63.

Subsequently, as illustrated in FIG. 10I, the interlayer insulating layer 72 is formed on side surfaces of the selector 50 and the hard mask portion 63 by CVD, etc. Specifically, after the interlayer insulating layer 72 is formed on the structure obtained by the process of FIG. 10H, the interlayer insulating layer 72 is planarized. By this process, the structure illustrated in FIG. 10I is obtained.

Subsequently, the second wiring line 20 is formed on the hard mask portion 63 and the interlayer insulating layer 72, thereby obtaining the structure illustrated in FIG. 8.

As described above, in the present embodiment, similarly to the first embodiment, the interlayer insulating layer 71 formed of the first material is provided on a side surface of the magnetoresistance effect element 40. The interlayer insulating layer 72 formed of the second material which is different from the first material is provided on a side surface of the selector 50. Thus, when the first material is selected so as to be suitable for the magnetoresistance effect element 40 (in other words, so as not to have a detrimental effect on the magnetoresistance effect element 40), and the second material is selected so as to be suitable for the selector 50 (in other words, so as not to have a detrimental effect on the selector 50), a magnetic memory device having excellent characteristics can be obtained.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A magnetic memory device comprising a stacked structure in which a magnetoresistance effect element and a switching element are stacked, wherein
the switching element is provided on a lower layer side of the magnetoresistance effect element, and
when viewed in a stacking direction of the magnetoresistance effect element and the switching element, a pattern of the switching element is located inside a pattern of the magnetoresistance effect element.

2. The device of claim 1, further comprising:
a first insulating layer provided on a side surface of the magnetoresistance effect element and formed of a first material; and
a second insulating layer provided on a side surface of the switching element and formed of a second material different from the first material.

3. The device of claim 2, wherein
a concentration of nitrogen of the first material is lower than a concentration of nitrogen of the second material.

4. The device of claim 2, wherein
a concentration of hydrogen of the second material is lower than a concentration of hydrogen of the first material.

5. The device of claim 2, wherein
the first material is oxide, and the second material is nitride.

6. The device of claim 2, wherein
the first material and the second material contain silicon (Si), nitrogen (N) and hydrogen (H), and
a composition ratio of silicon (Si), nitrogen (N) and hydrogen (H) of the first material is different from a composition ratio of silicon (Si), nitrogen (N) and hydrogen (H) of the second material.

7. The device of claim 1, wherein
the magnetoresistance effect element includes a first magnetic layer having a variable magnetization direction, a second magnetic layer having a fixed magnetization direction and a nonmagnetic layer provided between the first magnetic layer and the second magnetic layer.

8. The device of claim 1, further comprising:
a first wiring line extending in a first direction; and
a second wiring line extending in a second direction intersecting the first direction, wherein
the stacked structure is provided between the first wiring line and the second wiring line.

9. A magnetic memory device comprising;
a stacked structure in which a magnetoresistance effect element and a switching element are stacked;
a first insulating layer provided on a side surface of the magnetoresistance effect element and formed of a first material; and
a second insulating layer provided on a side surface of the switching element and formed of a second material different from the first material.

10. The device of claim 9, wherein
the switching element is provided on a lower layer side of the magnetoresistance effect element.

11. The device of claim 9, wherein
the switching element is provided on an upper layer side of the magnetoresistance effect element.

12. The device of claim 9, wherein
a concentration of nitrogen of the first material is lower than a concentration of nitrogen of the second material.

13. The device of claim 9, wherein
a concentration of hydrogen of the second material is lower than a concentration of hydrogen of the first material.

14. The device of claim 9, wherein
the first material is oxide, and the second material is nitride.

15. The device of claim 9, wherein
the first material and the second material contain silicon (Si), nitrogen (N) and hydrogen (H), and
a composition ratio of silicon (Si), nitrogen (N) and hydrogen (H) of the first material is different from a composition ratio of silicon (Si), nitrogen (N) and hydrogen (H) of the second material.

16. The device of claim 9, wherein
the magnetoresistance effect element includes a first magnetic layer having a variable magnetization direction, a second magnetic layer having a fixed magnetization direction and a nonmagnetic layer provided between the first magnetic layer and the second magnetic layer.

17. The device of claim 9, further comprising:
a first wiring line extending in a first direction; and
a second wiring line extending in a second direction intersecting the first direction, wherein
the stacked structure is provided between the first wiring line and the second wiring line.
